(19) United States
(12) Patent Application Publication
(10) Pub. No.: US 2002/0140013 A1
(43) Pub. Date: Oct. 3, 2002

(54) Structure and method for fabricating semiconductor structures and devices utilizing a stable template

(75) Inventors: Zhiyi Yu, Gilbert, AZ (US); Ravindranath Droopad, Chandler, AZ (US); Corey Overgaard, Phoenix, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Motorola, Inc.

(21) Appl. No.: 09/824,388

(22) Filed: Apr. 2, 2001

(51) Int. Cl. H01L 29/76; H01L 29/94; H01L 31/062; H01L 31/113; H01L 31/119

(52) U.S. Cl. 257/295

(57) ABSTRACT

High quality ionicly-bonded semiconductor materials can be grown overlying covalently-bonded substrates (22), such as large silicon wafers, by utilizing a stable template layer (24). The template layer is formed of material consisting of alkaline earth metal, alkaline earth metal silicide, alkaline earth metal silicate and/or Zintl-type phase material. A high-quality ionicly-bonded semiconductor material (26) may then be grown over the template layer.

### FIELD OF THE INVENTION

This invention relates generally to semiconductor structures and devices and to a method for their fabrication, and more specifically to semiconductor structures and devices and to the fabrication and use of semiconductor structures, and devices that include an ionic semiconductor material layer and a covalent Group IV substrate.

### BACKGROUND OF THE INVENTION

For many years, attempts have been made to fabricate structures formed of monolithic semiconductor thin films, such as GaAs, on foreign Group IV substrates, such as silicon (Si). To achieve optimal characteristics of the structure, a high quality, low defect semiconductor layer is desired. However, attempts to grow semiconductor layers, for example, GaAs, on substrates have generally been unsuccessful, partly because the Group IV substrates are covalently-bonded (nonpolar) materials while the semiconductors are ionicly-bonded (polar) materials. This difference is sufficient to cause significant defects in the semiconductor material when grown overlying the substrate.

Epitaxial metal oxide, such as SrTiO₃, has been grown on Group IV substrates, such as Si, using molecular beam epitaxy to act as a transition layer. This transition layer may compromise the lattice difference between the Group IV substrate and the semiconductor material layer. However, the epitaxial oxide transition layer requires additional growth procedures and introduces more complexity and cost to the process. In addition, because the thickness of the epitaxial oxide layer is generally 2-100 nm, the diffusion of the metal and oxygen from the metal oxide into the semiconductor layer, which causes structure defects, poses a significant problem.

If a large area thin film of high quality semiconductor material was available at low cost, a variety of semiconductor devices could advantageously be fabricated in or using that film at a low cost compared to the cost of fabricating such devices beginning with a bulk wafer on semiconductor material or in an epitaxial film of such material on a bulk wafer of semiconductor material. In addition, if a thin film of high quality semiconductor material could be realized beginning with a bulk wafer such as a silicon wafer, an integrated device structure could be achieved that took advantage of the best properties of both the silicon and the high quality semiconductor material.

Accordingly, a need exists for a semiconductor structure that provides a high quality ionicly-bonded semiconductor overlying a covalently-bonded substrate comprising Group IV material and a process for making such a structure. In other words, there is a need for providing the formation of a covalently-bonded substrate comprising Group IV material that is compliant with a high quality ionicly-bonded semiconductor layer so that true two-dimensional growth can be achieved for the formation of quality semiconductor structures, devices and integrated circuits.

### BRIEF DESCRIPTION OF THE DRAWINGS

The present invention is illustrated by way of example and not limitation in the accompanying figures, in which like references indicate similar elements, and in which:

FIG. 1 illustrates schematically, in cross section, a device structure in accordance with an embodiment of the invention; and

FIG. 2 illustrates schematically, in cross section, a device structure in accordance with another embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE INVENTION

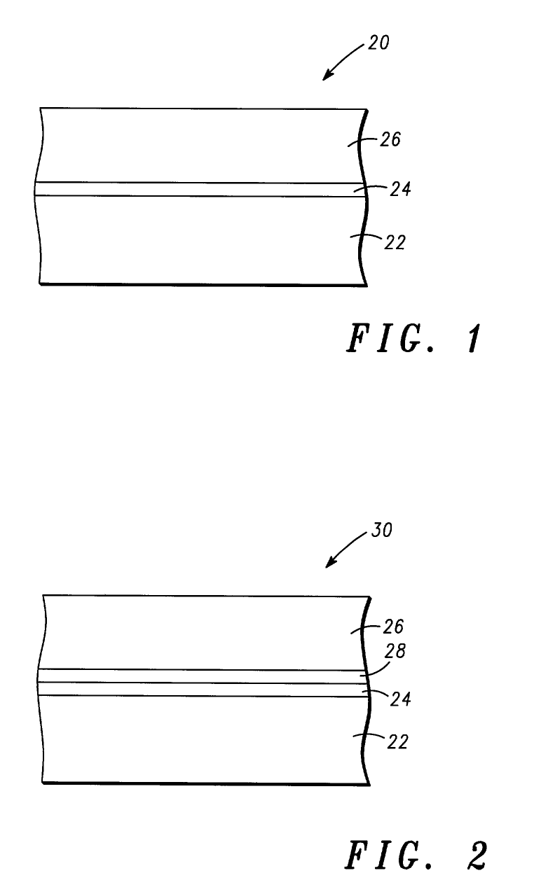

FIG. 1 illustrates schematically, in cross section, a portion of a semiconductor structure 20 in accordance with an embodiment of the invention. Semiconductor structure 20 includes a Group IV substrate 22, a template layer 24 and a semiconductor material layer 26. Substrate 22, in accordance with an embodiment of the invention, is an ionicly-bonded semiconductor, preferably of a large diameter. The wafer can be of, for example, a material or compound material from Group IV of the periodic table, and preferably a material from Group IVB, such as silicon (Si), germanium (Ge) or silicon germanium (SiGe). Preferably, substrate 22 is a wafer containing silicon.

In another embodiment of the invention, substrate 22 may comprise a (001) Group IV material that has been off-cut towards a (110) direction. The growth of materials on a miscut Si(001) substrate is known in the art. For example, U.S. Pat. No. 6,039,803, issued to Fitzgerald et al. on Mar. 21, 2000, which patent is herein incorporated by reference, is directed to growth of silicon-germanium and germanium layers on miscut Si(001) substrates. Substrate 22 may be off-cut in the range of from about 2 degrees to about 6 degrees towards the (110) direction. A miscut Group IV substrate reduces dislocations and results in improved quality of subsequently grown semiconductor material layer 26.

Template layer 24 may comprise a suitable material that chemically bonds to the covalently-bonded substrate and acts as a nucleating site for the subsequent deposition of the ionicly-bonded semiconductor material layer 26. Template layer 24 serves to lower the surface energy between the covalent substrate layer and the ionic semiconductor layer so that two-dimensional growth may occur with reduced defect potential. Template layer 24 may have a thickness in the range of from approximately one-half to one monolayer and may comprise any suitable alkaline earth metal, alkaline earth metal silicide or alkaline earth metal silicate layer that does not readily diffuse into the compound semiconductor material layer 26. Suitable materials for template layer 24 include strontium (Sr), barium (Ba), magnesium (Mg) or calcium (Ca) or any suitable silicide or silicate compound thereof. Template layer 24 may be formed by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Template layer 24 preferably is formed of Sr, which tends to diffuse into the subsequently grown semiconductor layer to a lesser extent than SrTiO₃

In another embodiment, template layer 24 may be formed of an intermetallic material that uses Zintl-type bonding to reduce the surface energy of the interface between the substrate and the semiconductor material layer. Template layer 24 may comprise a thin layer of Zintl-type phase material composed of metals and metalloids having a great deal of ionic character. Template layer 24 may be deposited by way of MBE, CVD, MOCVD, MEE, ALE, PVD, CSD, PLD, or the like to achieve a thickness of one-half to one monolayer. The Zintl-type phase material functions as a “soft” layer with non-directional bonding which absorbs stress build-up due to the phase shift between the covalent substrate layer and the ionic semiconductor material layer. Suitable Zintl-type phase materials include, but are not limited to, materials containing Sr, Al, Ga, In and Sb such as, for example, SrAl₂, (MgCaYb)Ga₂, (Ca,Sr,Eu,Yb)In₂, BaGe₂As, and SrSn₂As₂.

The substrate/template layer structure produced by use of the Zintl-type template layer can absorb a large strain without a significant energy cost. When the Zintl-type template layer is formed of SrAl₂, the bond strength of the Al is adjusted by changing the volume of the SrAl₂ layer thereby making the device tunable for specific applications, which include the monolithic integration of III-V and Si devices.

A semiconductor material layer 26 is epitaxially grown over template layer 24 to achieve the final structure illustrated in FIG. 1. The semiconductor material layer 26 can be selected, as desired, for a particular structure or application. For example, the material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), mixed II-VI compounds, Group IVB and VIB elements (IV-VI semiconductor compounds) and mixed IV-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), and the like. However, semiconductor material layer 26 may also comprise other ionic semiconductor materials, metals, or non-metal materials that are used in the formation of semiconductor structures, devices and/or integrated circuits.

FIG. 2 illustrates, in cross-section, a portion of a semiconductor structure 30 in accordance with a further embodiment of the invention. Structure 30 is similar to the previously described semiconductor structure 20, except that an additional surfactant layer 28 is positioned between the template layer 24 and the semiconductor material layer 26. Surfactant layer 28 may comprise, but is not limited to, elements such as aluminum (Al), indium (In) and gallium (Ga), and compounds such as strontium aluminum (SrAl₂), but may be dependent upon the composition of template layer 24 and semiconductor material layer 26 for optimal results. In one exemplary embodiment, SrAl₂, which has a similar structure to GaAs, is used for surfactant layer 28 and functions to modify the surface and surface energy of substrate 22 and template layer 24. Preferably, surfactant layer 28 is grown to a thickness of approximately one-half to one monolayer, over template layer 24 by way of MBE, CVD, MOCVD, MEE, ALE, PVD, CSD, PLD or the like.

The following example illustrates a process, in accordance with one embodiment of the invention, for fabricating a semiconductor structure such as the structure depicted in FIG. 1. The process starts by providing a monocrystalline semiconductor substrate comprising silicon or germanium. In accordance with a preferred embodiment of the invention, the semiconductor substrate is a (100) silicon wafer which has been miscut towards the (110) direction by approximately 2 to 6 degrees.

At least a portion of the semiconductor substrate has a bare surface, although other portions of the substrate may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. In order to epitaxially grow a semiconductor material layer overlying the substrate, the amorphous native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface exhibits an ordered 2×1 structure. If an ordered 2×1 structure has not been achieved at this stage of the process, the structure may be exposed to additional strontium until an ordered 2×1 structure is obtained. The ordered 2×1 structure forms a template layer 24 for the ordered growth of overlying template layer 24.

Following the removal of the silicon oxide from the surface of the substrate, in accordance with one embodiment of the invention, the substrate is cooled to a temperature in the range of about 200-800° C. and a template layer of strontium is grown on the ordered 2×1 structure, for example, by molecular beam epitaxy. Template layer 24 of strontium is grown to a thickness in the range of from about 0.5 to about 1 monolayer.

Following the formation of the template layer, gallium and arsenic are subsequently introduced by way of MBE, CVD, MOCVD, MEE, ALE, PVD, CSD, PLD or the like. Gallium arsenide is then formed overlying template layer 24.

The structure illustrated in FIG. 2 can be formed by the process discussed above with the addition of a surfactant layer deposition step. In one exemplary embodiment, aluminum (Al) is used for surfactant layer 28. Preferably, the surfactant layer is epitaxially grown over the formed template layer to a thickness of one-half to one monolayer by MBE or any of the other suitable processes described above. Once the surfactant layer is formed over the template layer, the semiconductor layer, such as a GaAs layer, is epitaxially grown, as described above with reference to the process for growing structure 20.

Clearly, those embodiments specifically describing structures having ionic semiconductor portions and covalent Group IV semiconductor portions are meant to illustrate embodiments of the present invention and not limit the present invention. There are a multiplicity of other combinations and other embodiments of the present invention. For example, the present invention includes structures and methods for fabricating material layers that form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices and integrated circuits. By using embodiments of the present invention, it is now simpler to integrate devices that include polar and non-polar layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a covalent (non-polar) semiconductor or compound semiconductor wafer can be used in forming ionic (polar) material layers over the wafer. In this manner, the wafer is essentially a “handle” wafer used during the fabrication of semiconductor electrical components within an ionic compound semiconductor material layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of semiconductor material wafers by placing them over a relatively more durable and easy to fabricate base material. Therefore, an integrated circuit can be formed such that all electrical components, and particularly all active electronic devices, can be formed within or using the ionic material layer even though the substrate itself may include a covalent semiconductor material. Fabrication costs for semiconductor devices should decrease because larger substrates can be processed more economically and more readily compared to the relatively smaller and more fragile substrates (e.g., conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a substrate formed of covalent material;
a template layer overlying said substrate and formed of a material selected from the group consisting of an alkaline earth metal, an alkaline earth metal silicide, an alkaline earth metal silicate and a Zintl-type phase material; and
an ionic semiconductor material layer overlying said template layer.

2. The semiconductor structure of claim 1 further comprising a surfactant layer overlying said template layer and underlying said ionic semiconductor material layer.

3. The semiconductor structure of claim 1 wherein said substrate comprises semiconductor material having an orientation from about 2 degrees to about 6 degrees offset towards a (110) direction.

4. The semiconductor structure of claim 1, wherein said substrate comprises Group IV semiconductor material.

5. The semiconductor structure of claim 4, wherein said substrate comprises silicon.

6. The semiconductor structure of claim 1 wherein said template layer has a thickness in the range of from about 0.5 to about 1 monolayer.

7. The semiconductor structure of claim 1 wherein said template layer is formed of strontium.

8. The semiconductor structure of claim 2 wherein said surfactant layer is formed of material selected from the group consisting of aluminum, indium, gallium and strontium aluminum.

9. The semiconductor structure of claim 2 wherein said surfactant layer has a thickness in the range of from about 0.5 to about 1 monolayer.

10. The semiconductor structure of claim 1 wherein the Zintl-type phase material comprises at least one of SrAl₂, (MgCaYb)Ga₂, (Ca,Sr,Eu,Yb)ln₂, BaGe₂As, and SrSn₂AS₂.

11. The semiconductor structure of claim 1, wherein said ionic semiconductor material layer comprises Group III-V material.

12. The semiconductor structure of claim 11, wherein said ionic semiconductor material layer comprises gallium arsenide.

13. A process for fabricating a semiconductor structure comprising:
providing a substrate formed of covalent material;
forming a template layer overlying said substrate, wherein said template layer is formed of a material selected from the group consisting of an alkaline earth metal, an alkaline earth metal silicide, an alkaline earth metal silicate and a Zintl-type phase material; and
growing an ionic semiconductor material layer overlying said template layer.

14. The process of claim 13, further comprising forming a surfactant layer overlying said template layer and underlying said ionic semiconductor material layer.

15. The process of claim 13, further comprising miscutting said substrate from about 2 degrees to about 6 degrees from the (001) direction.

16. The process of claim 13, wherein said providing a substrate comprises providing a substrate formed of Group IV semiconductor material.

17. The process of claim 16, wherein said providing a substrate formed of Group IV semiconductor material comprises providing a substrate formed of silicon.

18. The process of claim 13, wherein said forming a template layer comprises forming a template layer having a thickness in the range of from about 0.5 to about 1 monolayer.

19. The process of claim 13, wherein said forming a template layer comprises forming a template layer of strontium.

20. The process of claim 14, wherein said forming a surfactant layer comprises forming a surfactant layer from material selected from the group consisting of aluminum, indium, gallium and strontium.

21. The process of claim 14, wherein said forming a surfactant layer comprises forming a surfactant layer having at thickness in the range of from about 0.5 to about 1 monolayer.

22. The process of claim 13, wherein said forming a template layer comprises forming a template later of Zintl-type phase material selected from the group consisting of SrAl₂, (MgCaYb)Ga₂, (Ca,Sr,Eu,Yb)In₂, BaGe₂As, and SrSn₂As₂.

23. The process of claim 13, wherein said growing an ionic semiconductor material layer comprises growing a Group III-V material layer.

24. The process of claim 23, wherein said growing a Group III-V material layer comprises growing a gallium arsenide layer.
